(19) United States
(12) Patent Application Publication
(10) Pub. No.: US 2004/0012025 A1
(43) Pub. Date: Jan. 22, 2004

(54) Anode for organic light emitting diodes

(76) Inventors: Hoi-Sing Kwok, Kowloon (HK); Man Wong, New Territories (HK); Cheng-feng Qiu, Kowloon (HK)

Correspondence Address: James A. LaBarre, BURNS, DOANE, SWECKER & MATHIS, L.L.P., P.O. Box 1404, Alexandria, VA, 22313-1404, US

(21) Appl. No.: 10/199,085

(22) Filed: Jul. 22, 2002

(51) Int. Cl. H01L 27/15

(52) U.S. Cl. 257/79

(57) ABSTRACT

An organic light emitting diode consisting of multiple organic layers, disposed between a transparent conducting anode and a metallic cathode. The anode is provided with a metal oxide layer to enhance the overall performance of the device, including higher power efficiency, lower voltage threshold and high current efficiency.

### FIELD OF THE INVENTION

This invention relates in general to flat panel displays based on emission from organic materials, known either as organic light emitting diodes or organic electroluminescent devices. Specifically, this invention relates to the anode used in such devices.

### BACKGROUND OF THE INVENTION

Organic electroluminescent devices are light emitting devices that are based on the passage of current through one or multiple organic thin layers and FIG. 1 shows a conventional structure. For polymer materials, it is possible to make a single layer organic device sandwiched between a cathode 1 and an anode 6. However, most organic devices are multilayer in nature. Usually, a hole transport layer 4 (HTL) and an electron transport layer 3 (ETL) are needed. One of these electron or hole transport layers can be the light emitting layer (EML), or another light emitting layer 9 (FIG. 2) is deposited between the ETL and the HTL. Examples of typical hole transport layers are TPD and NPB. Examples of electron transport materials are Alq₃ and MTDATA. Alq₃ and doped Alq₃ are usually used as the light emitting layer. Much work has been devoted to the optimization of the device structure in terms of the thicknesses of the various layers, and in synthesising new materials that are more efficient in transporting the carriers and in generating light emission.

Much work has also been devoted to the cathode and anode layers. For the cathode 1, usually a low work function metal is needed that can inject electrons into the device efficiently. Metals such as Mg, Ag and Al have been used. A thin buffer layer 2 is usually needed to enhance the performance of the electron injection process. Hung et al discovered that adding an insulating and very thin layer of LiF can enhance the electron injection efficiency of the cathode 1 significantly (L. S. Hung, C. W. Tang, and M. G. Mason, Appl. Phys. Lett. 70(2), pp152-154(1997)). Other types of insulators have also been attempted, such as CsF and ZnO. But LiF is found to be the best so far. It is believed that the function of the insulating layer is to generate interface dipoles that tend to align the Fermi level of the metal with the LUMO level of the electron transport layer.

There has also been much work aimed at improving the hole injection from the anode 6. The anode material is usually indium tin oxide (ITO), which is transparent and conductive. ITO is used almost exclusively becasue of the need to transmit the emitted light through a transparent electrode. It is much more difficult to make a transparent cathode than an anode. ITO has a Fermi level that is not quite matched to the organic hole transport layer. Various techniques have been invented to improve the hole injection efficiency, such as by plasma treatment of the ITO, ozone cleaning of the ITO, and other types of chemical treatment that can alter the Fermi level of the ITO. This is possible because the electrical properties of ITO depend strongly on the oxygen content.

There are other methods that aim to improve the hole injection by adding a buffer layer 5 to the emitting device. Forrest et al (U.S. Pat. No. 5,998,803) teaches a method where an organic layer 5 with a good conductivity is inserted between the anode and the ITO. The efficiency is improved somewhat. Recently, Shen et al teaches a method whereby a metal layer 5 is added between the anode 6 and the HTL 4 (Yulong Shen, Daniel B. Jacobs, George G. Malliaras, Goutam Koley, Michael G. Spencer, and Andronique Ioannidis, Adv. Mater. Vol.13(16) pp1234-1238(2001)). They observed a great increase in the hole injection efficiency.

### SUMMARY OF THE INVENTION

According to the present invention there is provided an organic light-emitting device comprising a cathode layer, an organic light emitting layer, a transparent conducting anode layer and a metal oxide layer deposited between the said anode layer and the said organic light emitting layer.

By providing a layer on top of the anode both the hole injection efficiency and the light emission efficiency of the organic device can be improved.

Preferably the metal oxide layer is selected from the group consisting of praseodymium oxide, yttrium oxide, zinc oxide, terbium oxide, rubidium oxide, gallium oxide, tin oxide and titanium oxide.

The anode is preferably ITO.

### BRIEF DESCRIPTION OF THE DRAWINGS

Some embodiments of the invention will now be describe by way of example and with reference to the accompanying drawings, in which:—

FIG. 1 shows the basic structure of a multi-layer organic light emitting diode,

FIG. 2 shows another basic structure of a multi-layer organic light emitting diode,

FIG. 3 shows the structure of a first embodiment of an organic light emitting diode according to the present invention,

FIG. 4 shows the structure of a second embodiment of an organic light emitting diode according to the present invention,

FIG. 5 shows the current-voltage characteristics of the OLEDs according to embodiments of the invention with various types of metal oxide buffer layers,

FIG. 6 shows the emission power efficiency of the OLEDs according to embodiments of the invention as a function of the brightness of the display,

FIG. 7 shows the emission current efficiency of the OLEDs according to embodiments of the invention as a function of the brightness of the display, and

FIG. 8 shows the emission efficiency of the OLEDs according to embodiments of the invention as a function of the thickness of the metal oxide layer.

### DETAILED DESCRIPTION OF THE PREFERRED EMBODIMENTS

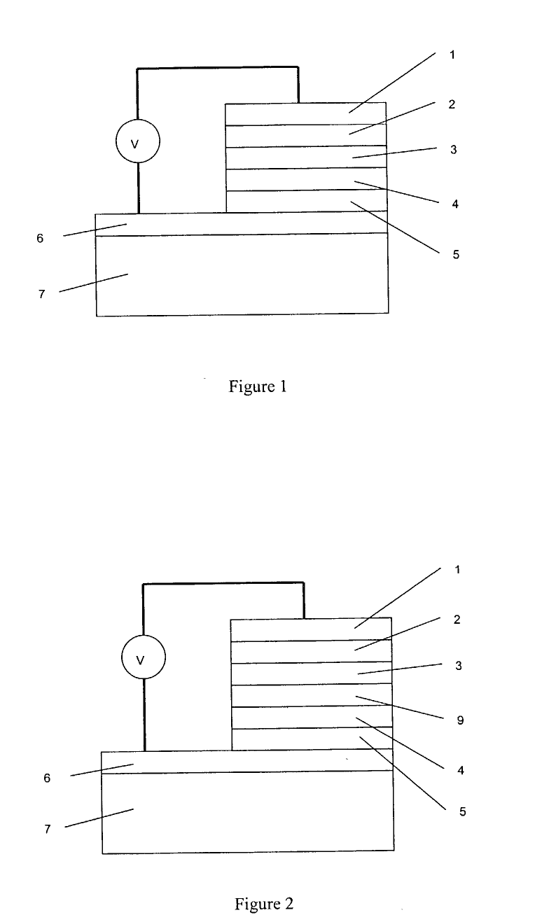

FIG. 1 shows the basic structure of a typical organic light emitting diode. It consists of a cathode layer 1, a cathode buffer layer 2, an electron transport layer 3, a hole transport layer 4, an anode buffer layer 5, and an anode layer 6. The structure is usually deposited on a substrate 7. Light is usually emitted from the electron transport layer 3 or the hole transport layer 4.

FIG. 2 shows a common variation of the basic structure where a light emitting layer 9 is added between the electron transport layer 3 and the hole transport layer 4.

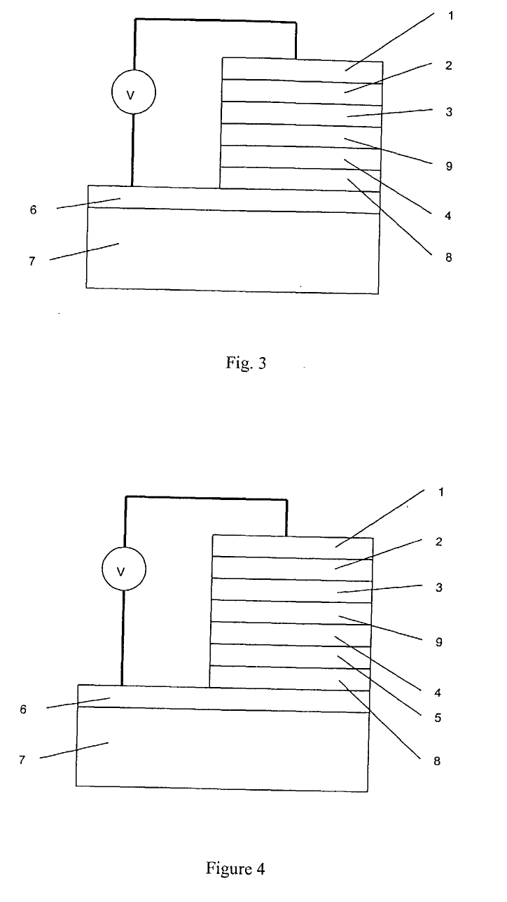

FIG. 3 shows a first embodiment of the present invention. A metal oxide layer 8 is added between the anode 6 and the hole transport layer 4. Anode buffer layer 5 is not used.

FIG. 4 shows the second embodiment of the present invention. A metal oxide layer 8 is added between the anode 6 and the hole-side organic buffer layer 5 used for energy level matching.

In both the first embodiment and the second embodiment of the present invention, the basic structure in FIG. 1 or 2 are applicable. The light can be emitted from the electron transport layer 3 or the hole transport layer 4 or another light emitting layer 9 provided between 3 and 4.

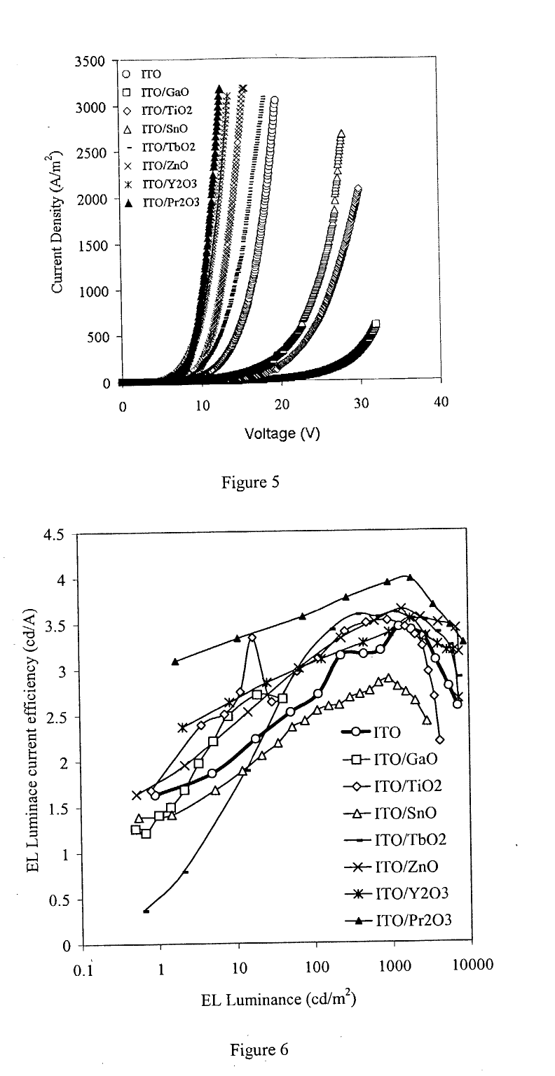

The addition of this oxide layer 8 to the light emitting device is beneficial to the operation of the OLED if the material is chosen properly. For the proper materials, the threshold voltage of the diode is decreased, and the light emission efficiency is increased. FIGS. 5 to 8 show some experimental results obtained using the structure of FIG. 4 with ITO as the anode material and using various metal oxdes.

FIG. 5 shows the current-voltage characteristics of several devices with various metal oxide layers. It can be seen that for most metal oxides 8, the operating voltage is decreased relative to the one without any metal oxide layer 8. Praseodymium oxide is found to be the best in terms of decrease of the voltage threshold.

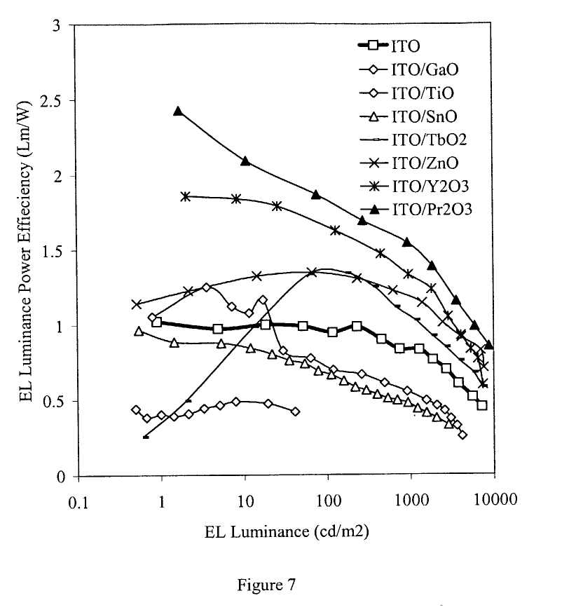

FIGS. 6 and 7 show the emission power efficiency and the current efficiency of the OLED device as a function the emission brightness for various metal oxides. Again it can be seen that the efficiency of the device containing praseodymium oxide is higher than that without any oxide by more than a factor of two.

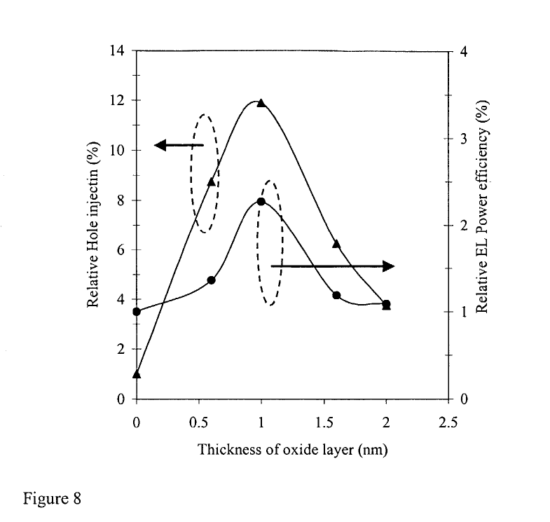

The thickness of the metal oxide has to be optimized as well. For large thicknesses, the device is adversely affected since the flow of holes is impeded. For too thin a layer, the effect of energy level matching or dipole alignment is insignificant. FIG. 8 shows the emission power efficiency of the OLED as a function of the thickness of the praseodymium oxide layer. It can be seen that in this case, the thickness should be 1 nm in order for the device to be optimized.

What is claimed is:

1. An organic light-emitting device comprising
a. a cathode layer
b. an organic light emitting layer
c. a transparent conducting anode layer
d. a metal oxide layer deposited between the said anode layer and the said organic light emitting layer.

2. A device as claimed in claim 1 wherein the said metal oxide layer is selected from the group consisting of praseodymium oxide, yttrium oxide, zinc oxide, terbium oxide, rubidium oxide, gallium oxide, tin oxide, and titanium oxide.

3. A device as claimed in claim 2 wherein the thickness of said metal oxide layer is 0.5-3 nanometer.

4. A device as claimed in claim 1 wherein the said anode layer is formed of indium tin oxide.

5. A device as claimed in claim 1 wherein the said cathode layer is formed of magnesium or aluminum or silver or a combination thereof.

6. A device as claimed in claim 1 wherein an additional organic hole transport layer is provided between the said metal oxide layer and the said organic light emitting layer.

7. A device as claimed in claim 1 wherein an additional organic buffer layer is provided between the said metal oxide layer and the said organic hole transport layer.

8. A device as claimed in claim 7 wherein the said organic buffer layer is formed of copper phthalocyanine (CuPc).

9. A device as claimed in claim 1 wherein an additional organic electron transport layer is provided between the said cathode layer and the said organic light emitting layer.

10. A device as claimed in claim 1 wherein an additional inorganic insulating layer is provided between the said cathode layer and the said organic light emitting layer.

11. A device as claimed in claim 10 wherein the said insulating layer is lithium fluoride.

12. A device as claimed in claim 1 wherein the metal cathode and the organic layers are formed by deposition on a substrate by thermal evaporation.

13. A device as claimed in claim 12 wherein the said substrate is glass or plastic or metal.

14. A device as claimed in claim 1 wherein the anode layer is formed by being deposited by sputtering.

15. A device as claimed in claim 1 wherein the metal oxide layer is formed by thermal evaporation.

16. A device as claimed in claim 1 wherein the metal oxide layer is deposited by sputtering.
